(19) United States
(12) Patent Application Publication
(10) Pub. No.: US 2025/0107188 A1
(43) Pub. Date: Mar. 27, 2025

(54) SiC JUNCTION FIELD EFFECT TRANSISTOR AND SiC COMPLEMENTARY JUNCTION FIELD EFFECT TRANSISTOR

(71) Applicant: KYOTO UNIVERSITY, Kyoto-shi (JP)

(72) Inventors: Mitsuaki KANEKO, Kyoto-shi (JP); Shunya SHIBATA, Kyoto-shi (JP); Tsunenobu KIMOTO, Kyoto-shi (JP)

(73) Assignee: KYOTO UNIVERSITY, Kyoto-shi (JP)

(21) Appl. No.: 18/976,181

(22) Filed: Dec. 10, 2024

Related U.S. Application Data
(63) Continuation of application No. PCT/JP2023/025890, filed on Jul. 13, 2023.

(30) Foreign Application Priority Data
Jul. 14, 2022 (JP) 2022-112930

(51) Int. Cl. H01L 29/10; H01L 27/098; H01L 29/16; H01L 29/808

(52) U.S. Cl. CPC H10D 62/343; H10D 30/83; H10D 62/8325; H10D 84/87

(57) ABSTRACT

A SiC junction field effect transistor includes a SiC substrate, a first conductivity type channel region formed in the principal surface of the SiC substrate, a second conductivity type embedded gate region formed below the channel region on the principal surface side in the SiC substrate, and first conductivity type source region and drain region formed with the channel region interposed therebetween in the principal surface of the SiC substrate.

### CROSS-REFERENCE TO RELATED APPLICATIONS

This is a continuation of International Application No. PCT/JP2023/025890 filed on Jul. 13, 2023, which claims priority to Japanese Patent Application No. 2022-112930 filed on Jul. 14, 2022. The entire disclosures of these applications are incorporated by reference herein.

### BACKGROUND

The present invention relates to a SiC junction field effect transistor (hereinafter referred to as a “SiC JFET”) formed using a silicon carbide (SiC) substrate and a SiC complementary junction field effect transistor (hereinafter referred to as a “SiC complementary JFET”) formed using the SiC JFET and including an n-channel JFET and a p-channel JFET.

Currently, a semiconductor integrated circuit is mainly made of silicon (Si), and in an industrial field, there has been eagerly demanded an integrated circuit, e.g., for engine control in an automobile or an aircraft, monitoring of an automobile tire, or space electronics, which is impossible to be formed using Si and is operable at a high temperature of 200° C. or higher.

SiC has a bandgap about three times higher than that of Si, and therefore, an integrated circuit operable under a high-temperature environment of 500° C. or higher can be produced using SiC.

As an integrated circuit produced using a SiC substrate, for example, S. H. Ryu et al., IEEE Trans. Electron Devices, vol. 45 (1998), p. 45 (Non-Patent Document 1) discloses an integrated circuit formed using a complementary MOSFET. Moreover, Japanese Unexamined Patent Publication No. 2011-166025 (Patent Document 1) discloses a complementary JFET configured such that an n-channel JFET and a p-channel JFET are insulated and separated from each other by a semi-insulating SiC layer.

### SUMMARY

However, in the complementary MOSFET disclosed in Non-Patent Document 1, high-density defect or charge is present at an interface between a SiC substrate and a gate oxide film, which leads to a problem that a threshold voltage greatly changes according to a temperature and stable operation cannot be performed. Moreover, there is also a problem that the gate oxide film is degraded due to a high temperature.

The complementary JFET disclosed in Patent Document 1 has such a structure that the n-channel JFET and the p-channel JFET are insulated and separated from each other by the intrinsic SiC layer formed by a hot-wall CVD method, and a trench formation process, an embedding and growing process, and a polishing process for surface flattening need to be finely repeated, which leads to a problem that a production process is extremely complicated.

So far, studies on the integrated circuit using the SiC board have been reported, but only operation under a high temperature has been confirmed. Any of these studies fails to solve the problems such as unstable operation at a high temperature and a difficulty in production of a complementary logic circuit, and such an integrated circuit is not yet put into practical use.

The present invention has been made in view of the above-described problems, and a main object thereof is to provide a SiC junction field effect transistor which is stably operable at a high temperature and from which a complementary JFET can be easily produced.

A SiC junction field effect transistor according to the present invention includes a SiC substrate, a first conductivity type channel region formed in the principal surface of the SiC substrate, a second conductivity type embedded gate region formed below the channel region on the principal surface side in the SiC substrate, and first conductivity type source region and drain region formed with the channel region interposed therebetween in the principal surface of the SiC substrate.

A SiC complementary junction field effect transistor according to the present invention includes an n-channel junction field effect transistor and a p-channel junction field effect transistor in a SiC substrate, each of the n-channel junction field effect transistor and the p-channel junction field effect transistor is the normally-off SiC junction field effect transistor, and the n-channel junction field effect transistor and the p-channel junction field effect transistor are formed apart from each other with electrically insulated from each other in the SiC substrate.

Another SiC junction field effect transistor according to the present invention includes a SiC substrate, a first conductivity type embedded channel region formed apart downward from the principal surface of the SiC substrate, a second conductivity type embedded gate region formed below the embedded channel region, and first conductivity type source region and drain region formed with the embedded channel region interposed therebetween in the principal surface of the SiC substrate.

According to the present invention, the SiC junction field effect transistor which is stably operable at a high temperature and from which the complementary JFET can be easily produced can be provided.

### BRIEF DESCRIPTION OF THE DRAWINGS

FIG. 1A shows a schematic plan view of the configuration of a SiC JFET in a first embodiment of the present invention.

FIG. 1B shows a sectional view taken along IB-IB line in FIG. 1A.

FIG. 1C shows a sectional view taken along IC-IC line in FIG. 1A.

FIG. 2A shows graphs obtained by simulation and showing the profile of an impurity density in a depth direction from a channel region surface when a channel region and an embedded gate region are formed by ion implantation in an n-channel JFET in the present embodiment.

FIG. 2B shows graphs of measurement results, which are obtained using SIMS, of the profile of the impurity density when the channel region and the embedded gate region are formed under ion implantation conditions set as shown in FIG. 2A.

FIG. 3A shows graphs of measurement results of drain current-drain voltage characteristics of an n-channel SiC JFET.

FIG. 3B shows graphs of measurement results of drain current-drain voltage characteristics of a p-channel SiC JFET.

FIG. 4 shows a circuit diagram in a case where an inverter circuit is formed using a SiC complementary JFET which is formed using the SiC JFET.

FIG. 5 shows a schematic sectional view of the structure of the SiC complementary JFET forming the inverter circuit.

FIG. 6A shows a schematic sectional view of a modification of the SiC complementary JFET forming the inverter circuit.

FIG. 6B shows a sectional view taken along VIB-VIB line in FIG. 6A.

FIG. 7A shows a schematic plan view of the configuration of a SiC JFET in a second embodiment of the present invention.

FIG. 7B shows a sectional view taken along VIIB-VIIB line in FIG. 7A.

FIG. 7C shows a sectional view taken along VIIC-VIIC line in FIG. 7A.

FIG. 8 shows a schematic sectional view of the structure of a SiC complementary JFET forming an inverter circuit.

FIG. 9A shows a schematic sectional view of another configuration of the SiC complementary JFET forming the inverter circuit.

FIG. 9B shows a sectional view taken along IXB-IXB line in FIG. 9A.

FIG. 10A shows a schematic plan view of the configuration of a SiC JFET in a modification of the second embodiment.

FIG. 10B shows a sectional view taken along XB-XB line in FIG. 10A.

FIG. 10C shows a sectional view taken along XC-XC line in FIG. 10A.

FIG. 11 shows a schematic sectional view of the configuration of a SiC JFET of another modification.

FIG. 12 shows a sectional view of the structure of a SiC JFET disclosed in a specification previously filed by the applicant(s) of the present application.

FIG. 13A shows graphs obtained by simulation and showing the profile of an impurity density in a depth direction from a gate region surface when an embedded channel region and a gate region are formed by ion implantation in an n-channel JFET shown in FIG. 12.

FIG. 13B shows graphs of measurement results, which are obtained using SIMS, of the profile of the impurity density when the embedded channel region and the gate region are formed under ion implantation conditions set as shown in FIG. 13A.

### DETAILED DESCRIPTION

The applicant(s) of the present application has disclosed, in the specification of the previously-filed application (Japanese Unexamined Patent Publication No. 2017-212397), the structure of a SiC JFET operating in a normally-off state over a broad gate voltage range. FIG. 12 shows a sectional view of an example of the structure of the SiC JFET disclosed in such a specification. Here, an n-channel JFET will be described, but a p-channel JFET also has a similar structure.

As shown in FIG. 12, the SiC JFET disclosed in the specification above includes an n-type embedded channel region 111 formed on a principal surface side in a SiC substrate 110, a p⁺-type gate region 114 formed above the embedded channel region 111, and n⁺-type source region 112 and drain region 113 formed with the gate region 114 interposed therebetween.

In the case of an n-channel SiC JFET, the threshold voltage Vₜₕ of the SiC JFET having the configured described above can be expressed using a model for analyzing a depletion layer at a semiconductor pn junction by Expression (1) below. Note that the threshold voltage Vₜₕ of a p-channel SiC JFET can also be expressed by a similar expression.

$${V}_{th} = \frac{kT}{q} ln ( \frac{np}{{n}_{i}^{2}} ) - \frac{{qNa}^{2}}{2 {ε}_{s}} \qquad ( 1 )$$

where k is a Boltzmann constant, n is the electron density of the embedded channel region 111, p is the hole density of the gate region 114, nᵢ is an intrinsic carrier density, q is an electron charge, εₛ is the dielectric constant of SiC, N is the impurity density of the embedded channel region 111, and a is the thickness of the embedded channel region 111 immediately below the gate region 114.

As shown in Expression (1), the threshold voltage Vₜₕ of the SiC JFET can be controlled by adjustment of the impurity density N and thickness a of the embedded channel region 111 immediately below the gate region 114. Moreover, the impurity density N and thickness a of the embedded channel region 111 are set to predetermined values such that the threshold voltage Vₜₕ becomes a positive value, and in this manner, a normally-off SiC JFET can be provided.

A SiC complementary JFET including the normally-off n-channel SiC JFET and p-channel SiC JFET can be easily manufactured in such a manner that the embedded channel region 111, gate region 114, source region 112, and drain region 113 having different conductivity types are formed in the same SiC substrate 110 by ion implantation.

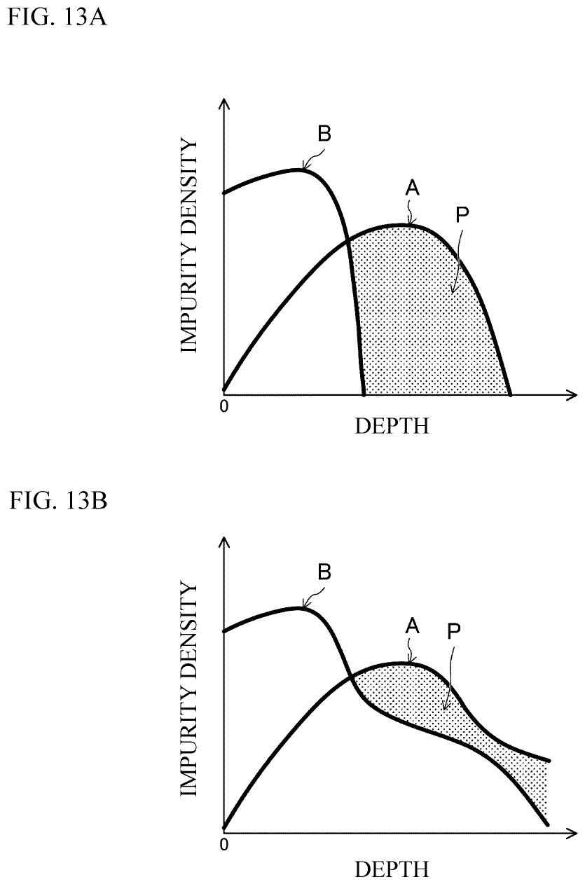

FIG. 13A shows graphs obtained by simulation and showing the profile of the impurity density in a depth direction from the surface of the gate region 114 when the n-type embedded channel region 111 and the p⁺-type gate region 114 are formed by the ion implantation in the n-channel JFET. Here, the graph indicated by an arrow A shows the profile of the embedded channel region 111, and the graph indicated by an arrow B shows the profile of the gate region 114. In FIG. 13A, a region indicated by an arrow P indicates the embedded channel region 111. Note that simulation software Stopping and Range in Matter (SRIM) for calculating the distribution of implanted ions by a Monte Carlo method was used for the simulation.

In order to obtain a target threshold voltage Vₜₕ, ion implantation conditions (dose amount and acceleration energy) were set such that the impurity density N and thickness a of the embedded channel region 111 are the predetermined values. Here, phosphorus (P) was used as an impurity for the n-type embedded channel region 111, and aluminum (Al) was used as an impurity for the p⁺-type gate region 114.

In the ion implantation, in a case where a dopant such as P or Al is implanted as an ion beam along a particular crystal direction of the SiC substrate, a channeling phenomenon occurs, in which an implanted atom reaches a deeper position as compared to a case where the dopant is not along the crystal direction. This channeling phenomenon influences the profile of the impurity density.

A method for reducing the influence of the channeling phenomenon includes a method in which the angle of the ion implantation to the SiC substrate is slightly inclined. However, even if such a method is employed, it is difficult for more implanted atoms to reach a position deeper than the peak of the profile of the impurity density.

FIG. 13B shows graphs of measurement results, which were obtained using secondary ion mass spectrometry (SIMS), of the profile of the impurity density when the embedded channel region 111 and the gate region 114 are formed under the ion implantation conditions set as shown in FIG. 13A. Here, the graph indicated by an arrow A shows the profile of the embedded channel region 111, and the graph indicated by an arrow B shows the profile of the gate region 114. In FIG. 13B, a region indicated by an arrow P indicates the embedded channel region 111.

As shown in FIG. 13B, the embedded channel region 111 and the gate region 114 are formed so as to expand their ranges to positions deeper than their peaks. Thus, the impurity in such an expanded portion of the high-density gate region 114 enters the low-density embedded channel region 111, and for this reason, the impurity density N of the embedded channel region 111 greatly decreases as compared to a design value while the thickness a of the embedded channel region 111 greatly increases as compared to a design value.

As described above, actual impurity density N and thickness a of the embedded channel region 111 greatly deviate from the design values, and for this reason, when the structure of the SiC JFET is designed, it is difficult to control the threshold voltage Vₜₕ of the SiC JFET as designed.

The inventor(s) et al. of the present application have devised a structure having no influence of the channeling phenomenon on the profile of the impurity density of the embedded channel region 111 even when the embedded channel region 111 and the gate region 114 are formed by the ion implantation, and have arrived at the present invention.

Hereinafter, embodiments of the present invention will be described in detail with reference to the drawings. Note that the present invention is not limited to the embodiments below. Moreover, changes can be made as necessary without departing from a scope in which the effects of the present invention are produced.

### First Embodiment

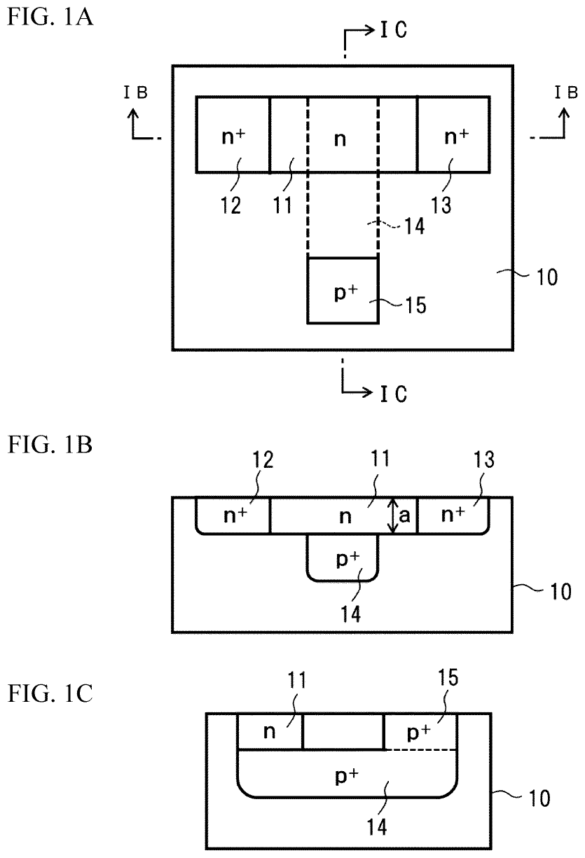

FIGS. 1A to 1C show schematic views of the configuration of a SiC JFET in a first embodiment of the present invention, FIG. 1A showing a plan view, FIG. 1B showing a sectional view taken along IB-IB line in FIG. 1A, and FIG. 1C showing a sectional view taken along IC-IC line in FIG. 1A. Here, an n-channel SiC JFET will be described.

As shown in FIGS. 1A to 1C, the SiC JFET in the present embodiment includes a semi-insulating SiC substrate 10, an n-type (first conductivity type) channel region 11 formed in a principal surface of the semi-insulating SiC substrate 10, a P⁺-type (second conductivity type) embedded gate region 14 formed below the channel region 11 on the principal surface side in the semi-insulating SiC substrate 10, and n⁺-type (first conductivity type) source region 12 and drain region 13 formed with the channel region 11 interposed therebetween in the principal surface of the semi-insulating SiC substrate 10. Note that in the present embodiment, the “principal surface” indicates a widest one of surfaces forming the semi-insulating SiC substrate 10.

Here, the impurity density of the channel region 11 is set lower than the impurity density of the embedded gate region 14. Moreover, all the channel region 11, the embedded gate region 14, the source region 12, and the drain region 13 are formed of ion-implanted layers.

As shown in FIGS. 1A and 1C, a p⁺-type (second conductivity type) gate contact region 15 is formed at a position apart from the source region 12 and the drain region 13 in the principal surface of the semi-insulating SiC substrate 10, and the embedded gate region 14 extends to immediately below the gate contact region 15 and is connected to the gate contact region 15.

Note that in the n-channel SiC JFET shown in FIGS. 1A to 1C, the semi-insulating SiC substrate 10 is used as a SiC substrate 10, but a SiC substrate 10 having a p-type epitaxial layer on a surface may be used. In this case, the channel region 11, the embedded gate region 14, the source region 12, and the drain region 13 are formed in the p-type epitaxial layer.

Note that a p-channel SiC JFET can be formed in such a manner that the channel region 11 is changed to a p-type, the embedded gate region 14 is changed to an n⁺-type, the source region 12 and the drain region 13 are changed to a p⁺-type, and the gate contact region 15 is changed to an n⁺-type.

In the case of the n-channel SiC JFET, the threshold voltage Vₜₕ of the SiC JFET in the present embodiment can be expressed by Expression (2) below when the impurity density of the channel region 11 is N_{D}, the impurity density of the embedded gate region 14 is N_{A}, and the thickness of the channel region 11 is a:

$${V}_{th} = \frac{kT}{q} ln ( \frac{np}{{n}_{i}^{2}} ) - \frac{{qN}_{D} {a}^{2}}{2 {ε}_{s}} \frac{{N}_{D} + {N}_{A}}{{N}_{A}} \qquad ( 2 )$$

where k is a Boltzmann constant, n is the electron density of the channel region 11, p is the hole density of the embedded gate region 14, nᵢ is an intrinsic carrier density, q is an electron charge, and εₛ is the dielectric constant of SiC. Note that the threshold voltage Vₜₕ of the p-channel SiC JFET can also be expressed by a similar expression.

In the SiC JFET in the present embodiment, the P⁺-type embedded gate region 14 is formed below the n-type channel region 11. However, since the embedded gate region 14 is formed of the ion-implanted layer, the impurity density N_{D} of the embedded gate region 14 is difficult to be a high density. For this reason, Expression (2) above is an expression in consideration of a case where a difference between the impurity density N_{D} of the channel region 11 and the impurity density N_{A} of the embedded gate region 14 is not so great, and in a case of N_{D}<<N_{A}, the threshold voltage Vth can be obtained using Expression (1) above.

As shown in Expression (2), the threshold voltage Vₜₕ of the SiC JFET can be controlled by adjustment of the impurity density N_{D} and thickness a of the channel region 11 and the impurity density N_{A} of the embedded gate region 14. Moreover, the impurity density N_{D} and thickness a of the channel region 11 and the impurity density N_{A} of the embedded gate region 14 are set to predetermined values such that the threshold voltage Vₜₕ becomes a positive value, and in this manner, a normally-off SiC JFET can be provided.

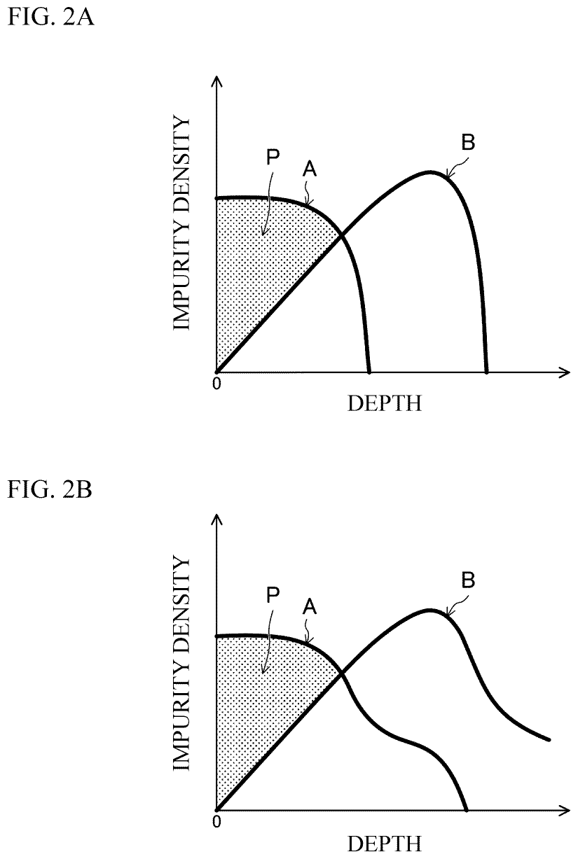

FIG. 2A shows graphs obtained by simulation and showing the profile of the impurity density in a depth direction from the surface of the channel region 11 when the n-type channel region 11 and the p⁺-type embedded gate region 14 are formed by ion implantation in the n-channel JFET. Here, the graph indicated by an arrow A shows the profile of the channel region 11, and the graph indicated by an arrow B shows the profile of the embedded gate region 14. In FIG. 2A, a region indicated by an arrow P indicates the channel region 11. Note that simulation software Stopping and Range in Matter (SRIM) for calculating the distribution of implanted ions by a Monte Carlo method was used for the simulation.

In order to obtain a target threshold voltage Vₜₕ, ion implantation conditions (dose amount and acceleration energy) were set such that the impurity density N_{D} and thickness a of the channel region 11 and the impurity density N_{A} of the embedded gate region 14 are the predetermined values. Here, phosphorus (P) was used as an impurity for the n-type channel region 11, and aluminum (Al) was used as an impurity for the p⁺-type embedded gate region 14.

FIG. 2B shows graphs of measurement results, which were obtained using secondary ion mass spectrometry (SIMS), of the profile of the impurity density when the channel region 11 and the embedded gate region 14 are formed under the ion implantation conditions set as shown in FIG. 2A. Here, the graph indicated by an arrow A shows the profile of the channel region 11, and the graph indicated by an arrow B shows the profile of the embedded gate region 14. In FIG. 2B, a region indicated by an arrow P indicates the channel region 11.

As shown in FIG. 2B, the channel region 11 and the embedded gate region 14 are formed so as to expand their ranges to positions deeper than their peaks, but the profiles of the impurity densities of the channel region 11 and the embedded gate region 14 at positions shallower than their peaks are not changed much from the profiles shown in FIG. 2A. Thus, actual impurity density N_{D} and thickness a of the channel region 11 and an actual impurity density N_{A} of the embedded gate region 14 are substantially coincident with design values shown in FIG. 2A. Thus, when the structure of the SiC JFET is designed, the threshold voltage Vₜₕ of the SiC JFET can be controlled as designed.

Note that FIGS. 2A and 2B show a case where the impurity density N_{D} of the channel region 11 is set lower than the impurity density N_{A} of the embedded gate region 14, but regardless of a magnitude relationship in the impurity density between these regions, the actual impurity density N_{D} and thickness a of the channel region 11 and the actual impurity density N_{A} of the embedded gate region 14 remain substantially coincident with the design values.

According to the present embodiment, the embedded gate region 14 is formed below the channel region 11 so that even in a case where the channel region 11 and the embedded gate region 14 are formed of the ion-implanted layers, the threshold voltage Vₜₕ of the SiC JFET can be controlled as designed without influence of a channeling phenomenon. Thus, a SiC JFET stably operable at a high temperature can be provided. Moreover, since all the channel region 11, the embedded gate region 14, the source region 12, and the drain region 13 are formed of the ion-implanted layers, a complementary JFET can be easily produced in the same SiC substrate 10.

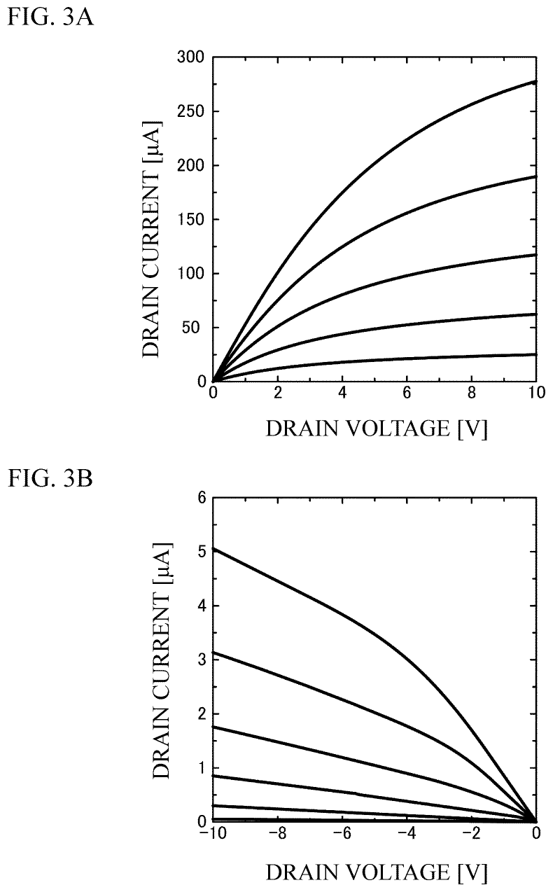

FIG. 3A shows graphs of measurement results of drain current-drain voltage characteristics when the n-channel SiC JFET having the configuration shown in FIGS. 1A to 1C is produced. Here, the measurement was conducted under a temperature of 300 K. Moreover, each ion-implanted layer was formed under the following conditions, and annealing after ion implantation was performed at 1650° C. Note that ion implantation was performed with an acceleration energy changed in multiple levels (multiple implantation). Moreover, the length of the channel region 11 was 50 μm, and the width of the channel region 11 was 100 μm.

### Channel Region 11

Impurity: P, Total Dose Amount: 1.57×10¹³ cm⁻², Acceleration Energy: 10-170 keV (multiple implantation)

### Embedded Gate Region 14

Impurity: Al, Total Dose Amount: 2.30×10¹³ cm⁻², Acceleration Energy: 450-520 keV (multiple implantation)

### Source Region 12/Drain Region 13

Impurity: P, Total Dose Amount: 4.23×10¹⁵ cm⁻², Acceleration Energy: 10-600 keV (multiple implantation)

In the n-channel SiC JFET produced under the above-described conditions, the impurity density of the channel region 11 was 5×10¹⁷ cm⁻³, the impurity density of the embedded gate region 14 was 1×10¹⁸ cm⁻³, and the thickness a of the channel region 11 was 281 nm.

As shown in FIG. 3A, the produced n-channel SiC JFET showed favorable drain current-drain voltage characteristics. Moreover, the threshold voltage Vₜₕ had only a difference of 0.1 V from the design value (−50.6 V).

FIG. 3B shows graphs of measurement results of drain current-drain voltage characteristics when the p-channel SiC JFET having the configuration shown in FIGS. 1A to 1C is produced. Here, the measurement was conducted under a temperature of 300 K. Moreover, each ion-implanted layer was formed by multiple implantation under the following conditions, and annealing after ion implantation was performed at 1650° C. The length of the channel region 11 was 50 μm, and the width of the channel region 11 was 100 μm.

### Channel Region 11

Impurity: Al, Total Dose Amount: 1.6×10¹³ cm⁻², Acceleration Energy: 10-220keV (multiple implantation)

### Embedded Gate Region 14

Impurity: P, Total Dose Amount: 2×10¹³ cm⁻², Acceleration Energy: 600-650 keV (multiple implantation)

### Source Region 12/Drain Region 13

Impurity: Al, Total Dose Amount: 3.67×10¹⁵ cm⁻², Acceleration Energy: 10-450 keV (multiple implantation)

In the p-channel SiC JFET produced under the above-described conditions, the impurity density of the channel region 11 was 5×10¹⁷ cm⁻³, the impurity density of the embedded gate region 14 was 1×10¹⁸ cm⁻³, and the thickness a of the channel region 11 was 281 nm.

### SiC Complementary JFET

FIG. 4 shows a circuit diagram in an example where an inverter circuit is formed using a SiC complementary JFET which is formed using the SiC JFET in the present embodiment. Here, Tᵣ₁ is a normally-off n-channel JFET, and Tᵣ₂ is a normally-off p-channel JFET. The gate electrodes G of the n-channel JFET and the p-channel JFET are connected to the input terminal Vᵢₙ of the inverter circuit. Moreover, the drain electrodes D of the n-channel JFET and the p-channel JFET are connected to the output terminal Vₒᵤₜ of the inverter circuit. Further, the source electrode S of the n-channel JFET is connected to the ground, and the source electrode S of the p-channel JFET is connected to a power source (V_{DD}).

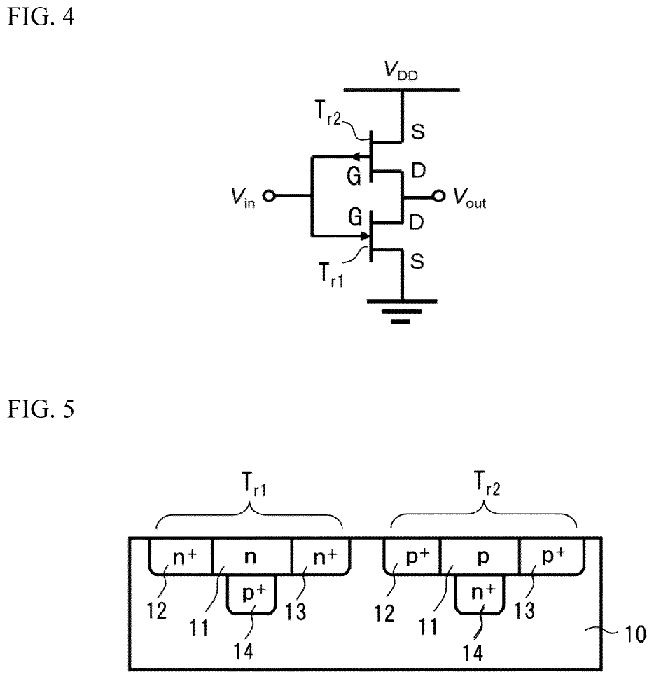

FIG. 5 shows a schematic sectional view of the structure of the SiC complementary JFET forming this inverter circuit.

As shown in FIG. 5, a n-type channel region 11 is formed in an n-channel JFET (Tᵣ₁) formation region of a semi-insulating SiC substrate 10, and a p-type channel region 11 is formed in a p-channel JFET (Tᵣ₂) formation region of the semi-insulating SiC substrate 10. Moreover, a p⁺-type embedded gate region 14 is formed immediately below the n-type channel region 11, and n⁺-type source region 12 and drain region 13 are formed with the channel region 11 interposed therebetween. Further, an n⁺-type embedded gate region 14 is formed immediately below the p-type channel region 11, and p⁺-type source region 12 and drain region 13 are formed with the channel region 11 interposed therebetween.

In the present embodiment, since all the channel region 11, the embedded gate region 14, the source region 12, and the drain region 13 are formed by ion implantation, the complementary JFET can be easily produced in the same SiC substrate 10. Moreover, since the n-channel JFET and the p-channel JFET are formed apart from each other in the semi-insulating SiC substrate 10, the n-channel JFET and the p-channel JFET can be easily electrically separated from each other. In addition, the impurity density N_{D} and thickness a of the channel region 11 can be set by adjustment of the acceleration energy and the dose amount in the ion implantation, and therefore, a normally-off JFET can be easily formed.

In the present embodiment, the semi-insulating SiC substrate 10 may have high resistance to such an extent that the n-channel JFET and the p-channel JFET can be electrically separated from each other. For example, a SiC substrate 10 having a resistivity p of 10⁹ Ωcm or more can be used.

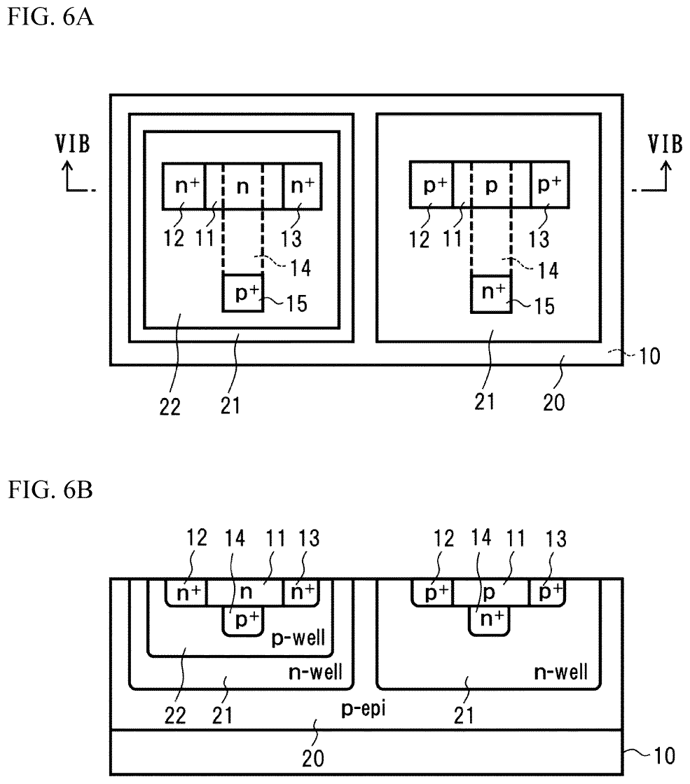

FIGS. 6A and 6B show schematic sectional views of a modification of the SiC complementary JFET formed using the SiC JFET in the present embodiment. Here, FIG. 6A is a plan view, and FIG. 6B is a sectional view taken along VIB-VIB line in FIG. 6A.

The SiC complementary JFET in the present modification is configured such that the n-channel JFET and p-channel JFET of the structure shown in FIGS. 1A to 1C are formed in a p⁻-type low-concentration epitaxial layer 20 formed on the SiC substrate 10.

As shown in FIGS. 6A and 6B, in the SiC complementary JFET in the present modification, two n-type well regions 21 apart from each other are formed in the p⁻-type low-concentration epitaxial layer 20. A p-type well region 22 is further formed in one of the well regions 21, and the n-channel JFET is formed in the p-type well region 22. Moreover, the p-type JFET is formed in the other well region 21. Thus, the n-channel JFET and the p-channel JFET can be electrically separated from each other in such a manner that a reverse bias is applied to a pn junction between the p⁻-type low-concentration epitaxial layer 20 and the n-type well region 21.

Note that even in a case where an n⁻-type low-concentration epitaxial layer is formed on the SiC substrate 10, a SiC complementary JFET having a similar configuration can be formed by changing the conductivity types of the well regions 21, 22.

### Second Embodiment

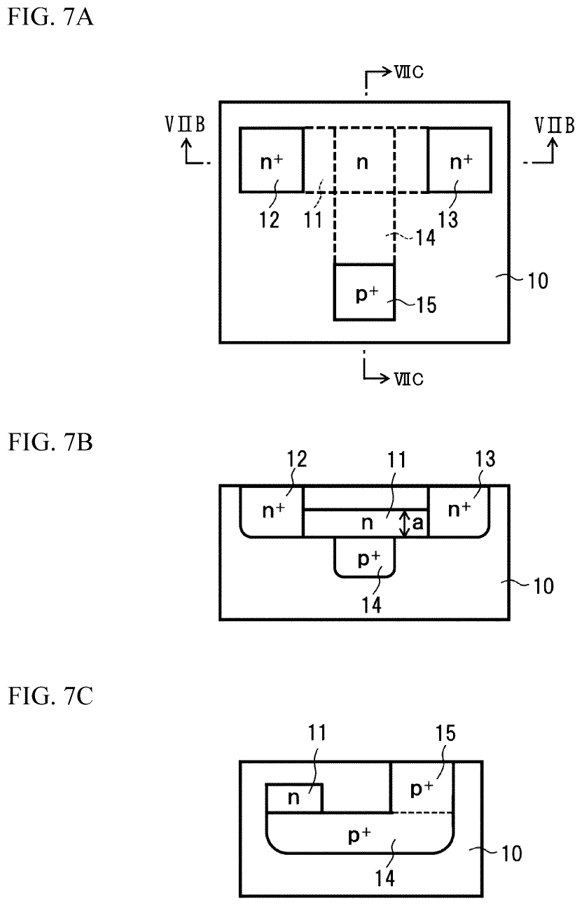

FIGS. 7A to 7C show schematic views of the configuration of a SiC JFET in a second embodiment of the present invention, FIG. 7A showing a plan view, FIG. 7B showing a sectional view taken along VIIB-VIIB line in FIG. 7A, and FIG. 7C showing a sectional view taken along VIIC-VIIC line in FIG. 7A. Here, an n-channel SiC JFET will be described.

In the SiC JFET in the first embodiment, the n-type (first conductivity type) channel region 11 is formed in the principal surface of the semi-insulating SiC substrate 10 as shown in FIGS. 1A to 1C. However, in the SiC JFET in the present embodiment, an n-type (first conductivity type) embedded channel region 11 is formed at a position apart downward from the principal surface of a semi-insulating SiC substrate 10 as shown in FIGS. 7A to 7C.

Note that as in the first embodiment, in the present embodiment, a p⁺-type (second conductivity type) embedded gate region 14 is formed below the embedded channel region 11, and n⁺-type (first conductivity type) source region 12 and drain region 13 are formed with the embedded channel region 11 interposed therebetween in the principal surface of the semi-insulating SiC substrate 10.

Moreover, a p⁺-type (second conductivity type) gate contact region 15 is formed at a position apart from the source region 12 and the drain region 13 in the principal surface of the semi-insulating SiC substrate 10, and the embedded gate region 14 extends to immediately below the gate contact region 15 and is connected to the gate contact region 15.

In a case where the channel region 11 is formed in the principal surface of the SiC substrate 10, if there is a charge in the surface of the SiC substrate 10, a depletion layer in the channel region 11 may be unintentionally extended when a voltage is applied to the embedded gate region 14, and for this reason, a threshold voltage Vₜₕ cannot be controlled as designed. In the present embodiment, since the embedded channel region 11 is formed at the position apart downward from the principal surface of the SiC substrate 10, variation in the threshold voltage Vₜₕ due to influence of the charge in the surface of the SiC substrate 10 can be reduced.

Here, the depth of the embedded channel region 11 from the principal surface of the SiC substrate 10 may be determined as necessary according to the amount of charge in the surface of the SiC substrate 10. Typically, the embedded channel region 11 may be formed at a position 3 to 500 nm lower than the principal surface of the SiC substrate 10, more preferably 20 to 300 nm lower than the principal surface. If the embedded channel region 11 is formed at a position less than 3 nm lower than the principal surface of the SiC substrate 10, it is difficult to avoid the influence of the charge in the surface of the SiC substrate 10. If the embedded channel region 11 is formed at a position more than 500 nm lower than the principal surface of the SiC substrate 10, the embedded gate region 14 needs to be formed at a deeper position, which leads to an increase in an energy in ion implantation and a cost.

As in the first embodiment, in the present embodiment, the embedded gate region 14 is formed below the embedded channel region 11, and therefore, even if the embedded channel region 11 and the embedded gate region 14 are formed of ion-implanted layers, the threshold voltage Vₜₕ of the SiC JFET can be controlled as designed without influence of a channeling phenomenon. Thus, a SiC JFET stably operable at a high temperature can be provided. Note that the impurity density of the embedded channel region 11 is preferably set lower than the impurity density of the embedded gate region 14.

All the embedded channel region 11, the embedded gate region 14, the source region 12, and the drain region 13 are preferably formed of the ion-implanted layers. With this configuration, a complementary JFET can be easily produced in the same SiC substrate 10.

The threshold voltage Vₜₕ of the SiC JFET can be controlled by adjustment of the impurity density N_{D} and thickness a of the embedded channel region 11 and the impurity density N_{A} of the embedded gate region 14. Moreover, the impurity density N_{D} and thickness a of the embedded channel region 11 and the impurity density N_{A} of the embedded gate region 14 are set to predetermined values such that the threshold voltage Vₜₕ becomes a positive value, and in this manner, a normally-off SiC JFET can be provided.

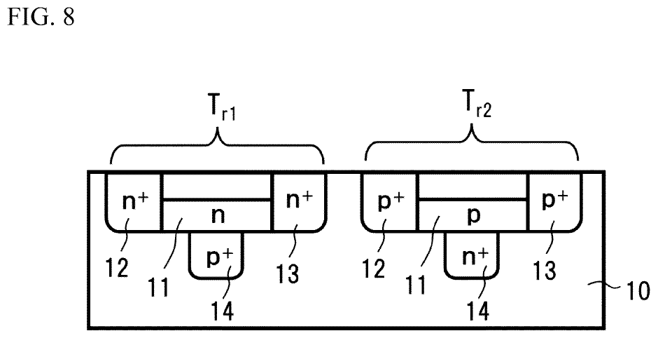

FIG. 8 shows a schematic sectional view of the structure of a SiC complementary JFET formed using the SiC JFET in the present embodiment and forming the inverter circuit shown in FIG. 4.

As shown in FIG. 8, an n-type embedded channel region 11 is formed in an n-channel JFET (Tᵣ₁) formation region of a semi-insulating SiC substrate 10, and a p-type embedded channel region 11 is formed in a p-channel JFET (Tᵣ₂) formation region of the semi-insulating SiC substrate 10. Moreover, a p⁺-type embedded gate region 14 is formed immediately below the n-type embedded channel region 11, and n⁺-type source region 12 and drain region 13 are formed with the embedded channel region 11 interposed therebetween. Further, an n⁺-type embedded gate region 14 is formed immediately below a p-type channel region 11, and p⁺-type source region 12 and drain region 13 are formed with the channel region 11 interposed therebetween.

In the present embodiment, since all the embedded channel region 11, the embedded gate region 14, the source region 12, and the drain region 13 are formed by ion implantation, the complementary JFET can be easily produced in the same SiC substrate 10. Moreover, since the n-channel JFET and the p-channel JFET are formed apart from each other in the semi-insulating SiC substrate 10, the n-channel JFET and the p-channel JFET can be easily electrically separated from each other. In addition, the impurity density N_{D} and thickness a of the channel region 11 can be set by adjustment of an acceleration energy and a dose amount in the ion implantation, and therefore, a normally-off JFET can be easily formed.

In the present embodiment, the semi-insulating SiC substrate 10 may have high resistance to such an extent that the n-channel JFET and the p-channel JFET can be electrically separated from each other. For example, a SiC substrate 10 having a resistivity p of 10⁹ Ωcm or more can be used.

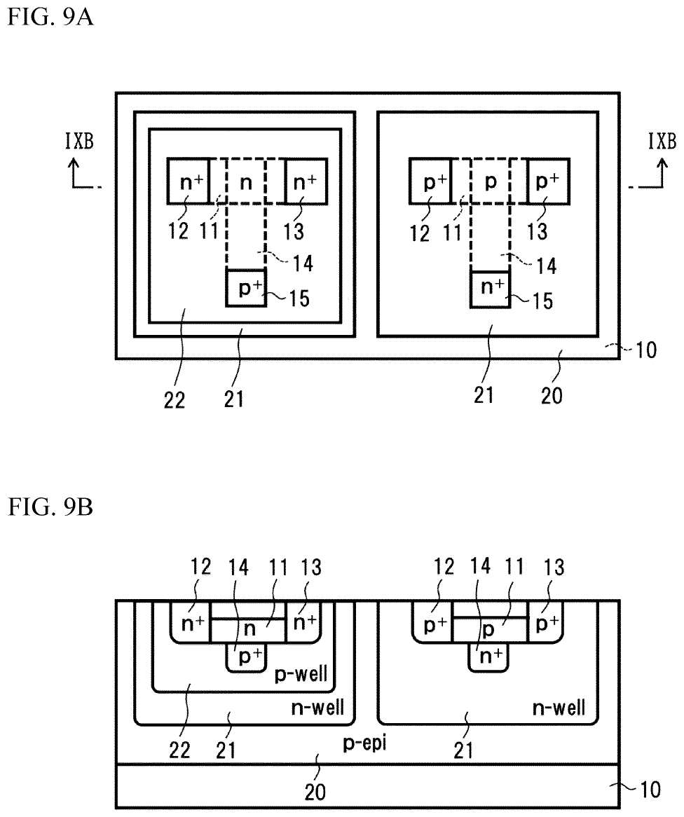

FIGS. 9A and 9B show schematic sectional views of another configuration of the SiC complementary JFET in the present embodiment, and the n-channel JFET and the p-channel JFET are formed in a p⁻-type low-concentration epitaxial layer 20 formed on the SiC substrate 10. Here, FIG. 9A is a plan view, and FIG. 9B is a sectional view taken along IXB-IXB line in FIG. 9A.

As shown in FIGS. 9A and 9B, two n-type well regions 21 apart from each other are formed in the p⁻-type low-concentration epitaxial layer 20. A p-type well region 22 is further formed in one of the well regions 21, and the n-channel JFET is formed in the well region 22. Moreover, the p-type JFET is formed in the other well region 21. Thus, the n-channel JFET and the p-channel JFET can be electrically separated from each other in such a manner that a reverse bias is applied to a pn junction between the p⁻-type low-concentration epitaxial layer 20 and the n-type well region 21.

Note that even in a case where an n⁻-type low-concentration epitaxial layer is formed on the SiC substrate 10, a SiC complementary JFET having a similar configuration can be formed by changing the conductivity types of the well regions 21, 22.

### Modification of Second Embodiment

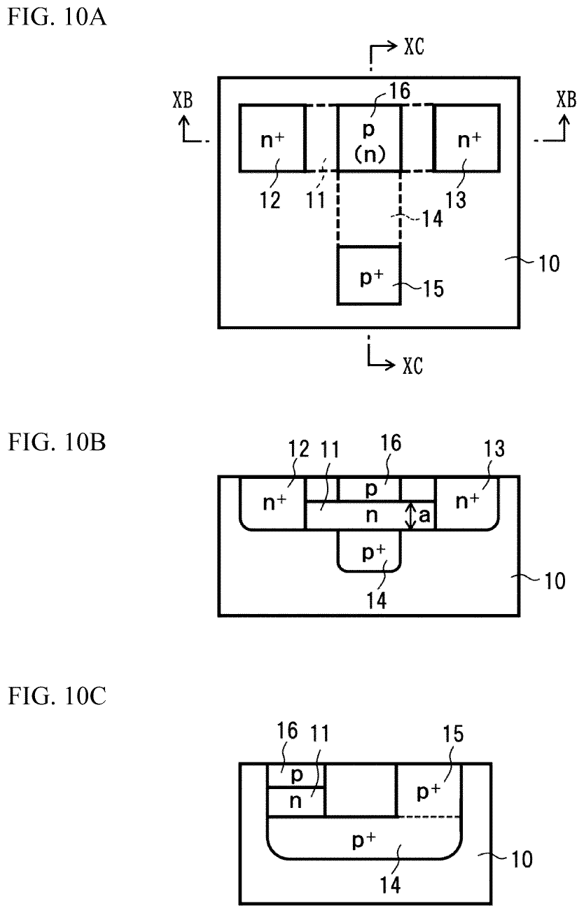

FIGS. 10A to 10C show schematic views of a modification of the SiC JFET shown in FIGS. 7A to 7C, FIG. 10A showing a plan view, FIG. 10B showing a sectional view taken along XB-XB line in FIG. 10A, and FIG. 10C showing a sectional view taken along XC-XC line in FIG. 10A. Here, an n-channel SiC JFET will be described.

The SiC JFET in the present modification is configured such that in the SiC JFET shown in FIGS. 7A to 7C, a p-type (second conductivity type) surface gate region 16 is formed above the embedded channel region 11 at a position facing the p⁺-type embedded gate region 14 in the principal surface of the SiC substrate 10. That is, the SiC JFET in the present modification has a double gate structure in which the embedded channel region 11 is sandwiched by the paired embedded gate region 14 and surface gate region 16.

With this configuration, the depletion layer in the embedded channel region 11 is controlled by the paired embedded gate region 14 and surface gate region 16 formed on both sides of the embedded channel region 11, and therefore, as compared to the single gate structure shown in FIGS. 7A to 7C, a drain current can be increased about twice for the same threshold voltage Vₜₕ. Thus, a SiC JFET having a high current drive capability can be provided.

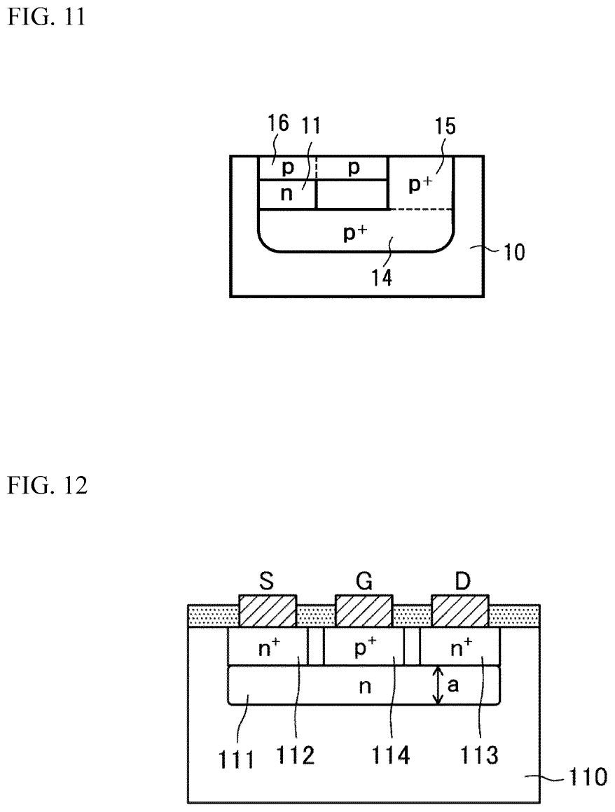

Note that in the present modification, in order to apply a gate voltage to both the embedded gate region 14 and the surface gate region 16, the surface gate region 16 is preferably connected to the gate contact region 15 via, e.g., wiring. As shown in FIG. 11, in order to connect the surface gate region 16 to the gate contact region 15, the surface gate region 16 may be extended to the gate contact region 15 in the principal surface. Alternatively, the surface gate region 16 may be formed as a gate different from the embedded gate region 14 without connected to the gate contact region 15 via, e.g., wiring, and different gate voltages may be applied to the embedded gate region 14 and the surface gate region 16 to control the depletion layer in the embedded channel region 11.

Note that in the present modification, the impurity density of the surface gate region 16 is preferably set lower than the impurity density of the embedded gate region 14. Thus, even if the surface gate region 16 is formed of an ion-implanted layer, the threshold voltage Vₜₕ of the SiC JFET can be controlled as designed with almost no influence of a channeling phenomenon on the embedded channel region 11.

The SiC complementary JFET having the structure shown in FIG. 8 or FIGS. 9A and 9B can be formed using the SiC JFET in the present modification.

The present invention has been described above with reference to the preferred embodiments, but the present invention is not limited to such description and various changes can be made thereto, needless to say.

For example, in the above-described embodiments, the example where the SiC complementary JFET is applied to the inverter circuit has been described, but the SiC complementary JFET may be applied to other integrated circuits, needless to say.

The structures of the SiC complementary JFETs shown in FIGS. 6A, 6B, 9A, and 9B can be applied to a SiC JFET alone.

The SiC JFETs in the above-described embodiments can be applied not only to the normally-off type but also a normally-on type, needless to say.

In the above-described embodiments, the example where the impurity density N_{D} of the channel region 11 or the embedded channel region 11 is set lower than the impurity density N_{A} of the embedded gate region 14 has been described, but both these regions may have a similar density.

What is claimed is:

1. A SiC junction field effect transistor comprising:
a SiC substrate;
a first conductivity type channel region formed in a principal surface of the SiC substrate;
a second conductivity type embedded gate region formed below the channel region on a principal surface side in the SiC substrate; and
first conductivity type source region and drain region formed with the channel region interposed therebetween in the principal surface of the SiC substrate.

2. The SiC junction field effect transistor of claim 1, wherein
an impurity density of the channel region is set lower than an impurity density of the embedded gate region.

3. The SiC junction field effect transistor of claim 1, wherein
all the channel region, the embedded gate region, the source region, and the drain region are formed of ion-implanted layers.

4. The SiC junction field effect transistor of claim 1, further comprising:
a second conductivity type gate contact region at a position apart from the source region and the drain region in the principal surface of the SiC substrate,
wherein the embedded gate region extends to immediately below the gate contact region, and is connected to the gate contact region.

5. A SiC complementary junction field effect transistor comprising:
a normally-off n-channel junction field effect transistor and a normally-off p-channel junction field effect transistor in a SiC substrate,
wherein each of the n-channel junction field effect transistor and the p-channel junction field effect transistor is the SiC junction field effect transistor of claim 1, and
the n-channel junction field effect transistor and the p-channel junction field effect transistor are formed apart from each other with electrically insulated from each other in the SiC substrate.

6. A SiC junction field effect transistor comprising:
a SiC substrate;
a first conductivity type embedded channel region formed apart downward from a principal surface of the SiC substrate;
a second conductivity type embedded gate region formed below the embedded channel region; and
first conductivity type source region and drain region formed with the embedded channel region interposed therebetween in the principal surface of the SiC substrate.

7. The SiC junction field effect transistor of claim 6, wherein
an impurity density of the embedded channel region is set lower than an impurity density of the embedded gate region.

8. The SiC junction field effect transistor of claim 6, wherein
all the embedded channel region, the embedded gate region, the source region, and the drain region are formed of ion-implanted layers.

9. The SiC junction field effect transistor of claim 6, further comprising:
a second conductivity type gate contact region at a position apart from the source region and the drain region in the principal surface of the SiC substrate,
wherein the embedded gate region extends to immediately below the gate contact region, and is connected to the gate contact region.

10. The SiC junction field effect transistor of claim 6, further comprising:
a second conductivity type surface gate region above the embedded channel region at a position facing the embedded gate region in the principal surface of the SiC substrate.

11. A SiC complementary junction field effect transistor comprising:
a normally-off n-channel junction field effect transistor and a normally-off p-channel junction field effect transistor in a SiC substrate,
wherein each of the n-channel junction field effect transistor and the p-channel junction field effect transistor is the SiC junction field effect transistor of claim 6, and
the n-channel junction field effect transistor and the p-channel junction field effect transistor are formed apart from each other with electrically insulated from each other in the SiC substrate.
